(19) United States
(12) Patent Application Publication
(10) Pub. No.: US 2009/0015317 A1
(43) Pub. Date: Jan. 15, 2009

(54) METHODS AND SYSTEMS FOR CONTROLLING QUBITS

(76) Inventors: David Peter DiVincenzo, Pleasantville, NY (US); Roger Hilsen Koch, Amawalk, NY (US)

Correspondence Address: F. CHAU & ASSOCIATES, LLC, 130 WOODBURY ROAD, WOODBURY, NY, 11797, US

(21) Appl. No.: 11/777,335

(22) Filed: Jul. 13, 2007

(51) Int. Cl. H03K 3/38

(52) U.S. Cl. 327/528

(57) ABSTRACT

A system for quantum computing includes a plurality of qubits and a control system. The control system generates control signals to control operation of the qubits and sets a bias point of each quit between a first position, in which the qubit is disabled and not responsive to the control signals, and a second positions in which the qubit is enabled and responsive to the control signals.

### BACKGROUND OF THE INVENTION

1. Field of the Invention

The present disclosure relates to quantum computing and, more particularly, to methods and systems for controlling qubits.

2. Description of Related Art

A “quantum computer” is an apparatus for information processing or computation that uses the quantum mechanical state of a physical system to represent the logical state of the apparatus. Quantum computing is an interdisciplinary field of research that seeks to develop technologies that can harness the inherent capacity of quantum systems to do massively parallel processing of information. Considerable research effort has been directed toward developing quantum computers, given that ideal quantum computers have been shown to be capable of carrying out certain information processing tasks more rapidly than ordinary digital (classical) computers and have the potential to efficiently solve problems believed to be intractable on classical computers.

In a classical computer, the logical state of the computer is represented in binary form as a “0” or “1”. A classical computer encodes information in a series of bits for computation that are normally manipulated via Boolean logic. In a classical computers the basic unit of a computation is a logic gate, which performs a logic operation on one or more logic inputs and produces a single logic output. In a quantum computer, the fundamental unit of information is a quantum two-state system, called a “quantum bit” or “qubit”. A qubit is the counterpart in quantum computing to the binary digit or bit of classical computing.

A quantum computer exploits the intrinsic parallelism of quantum physics in which the quantum state of a single object can behave as if it exists simultaneously in many possible classical configurations. Unlike classical bits, the qubit can exist not only in a state corresponding to the logical state 0 or 1 but in states corresponding to a superposition of these classical states, with a numerical coefficient representing the probability for each state. Hence, in a sense, the qubit can store the values 0 and 1 simultaneously.

Quantum computing generally involves initializing the states of N qubits, creating controlled entanglements among them, allowing these states to evolve, and reading out the states of the qubits after the evolution. The energy states of a qubit are generally referred to as the basis states of the qubit. A quantum computer uses the basis states of a quantum system, such as the “ground state” and “first excited state” abstracted as “|0>” and “|1>”, to perform a quantum computation. N qubits connected together could manipulate exponentially more information than N classical bits, although a hardware implementation of a large-scale quantum computer has not yet been realized.

An element in the search for practical quantum computer designs is finding an improved hardware implementation of the qubit. After successes with few-qubit systems, including demonstration of the Shor factorization algorithm with NMR (Nuclear Magnetic Resonance)—based techniques, existing qubit implementations (such as by NMR) have run into limitations of non-scalability.

Data loss or corruption can occur in a quantum computer due to interaction of qubits with particles in the environment causing changes in the qubit's quantum mechanical state. The tendency of a quantum computer to decay from a given state into an incoherent state as qubits interact, or entangle, with the environment is called “decoherence”. If the rate of decoherence is small enough, it may be possible to use quantum error correcting codes to correct errors. However the use of quantum error correcting codes brings with it the cost of an increased number of required qubits.

Like an ordinary classical computer, in a quantum computer, only a fraction of the qubits will be required to operate at any one time. The selection of which logic gates in a classical computer, or which qubits in a quantum computer, to operate at any given stage during an operation or algorithm requires a control system and control system architecture. This same control system must provide timing control for the single and multiple gate operations of the computer. The control system design and specification will depend intimately on the nature of the gates being controlled, be they classical or quantum gates.

To perform computations, a quantum computer using Josephson-junction-based qubits, for example, must operate at temperatures near absolute 0 K (typically 5 mK to 30 mK), and so multiplexing schemes for arrays of qubits are needed that also work at low temperatures. A conventional CMOS or superconducting SFQ (Single Flux Quantum) based multiplexer can operate at such low temperatures, but the heat generated by the multiplexer will be so large as to heat the multiplexer and the qubits beyond the temperature at which the qubits cease to work. Today's quantum computers avoid this issue by having the multiplexer in a room temperature environment and running a number of wires, e.g., 16 wires/qubit, between each one of the qubits working at typically 30 mK and the multiplexer at room temperature. Since the number of qubits currently being demonstrated is limited to 3, the number of wires to the qubits is relatively small and manageable. However, to build a quantum computer capable of solving actual problems, for example, a quantum computer using 1,000,000 qubits, the number of wires running from the qubits working at 30 mK to room temperature becomes unmanageable.

A need exists for improved control methods and control systems for controlling qubits in a quantum computer. There is a need for improved methods of multiplexing signals at the quantum computer operating temperature that do not generate excessive heat and that provide the requisite signal fidelity and addressability to enable operation of a quantum computer.

### SUMMARY OF THE INVENTION

According to an exemplary embodiment of the present invention, a system for quantum computing includes a plurality of qubits and a control system. The control system generates control signals to control operation of the qubits and sets a bias point of each quit between a first position, in which the qubit is disabled and not responsive to the control signals, and a second position, in which the qubit is enabled and responsive to the control signals.

According to an exemplary embodiment of the present invention, a method of controlling a quantum system comprising a plurality of qubits includes applying a deselect signal to each qubit to set a bias point of each qubit to a first position, in which the qubit is disabled and not responsive to a control signal, applying a select signal to one or more selected qubits to move the bias point from the first position to a second position, in which the qubit is enabled and responsive to the control signal, and applying the control signal commonly to the qubits to perform an operation, wherein only the selected qubits for which the bias point is in the second position are triggered to perform the operation.

According to an exemplary embodiment of the present invention, a method of controlling a plurality of qubits includes providing a plurality of qubits, wherein each of the qubits has at least two bias points on an operating characteristic of the qubit for which the lowest eigen-frequency is substantially the same, and generating signals for moving the bias point of selected qubits between the at least two bias points.

According to an exemplary embodiment of the present invention, a control system for controlling a plurality of qubits includes a control signal source commonly coupled to each qubit, which generates control signals to control operation of the qubits, and a plurality of select/deselect signal sources each coupled to a corresponding one of the qubits, wherein each select/deselect signal source independently operates to set a bias point of the corresponding qubit between a first position, in which the qubit is disabled and not responsive to the control signals, and a second position, in which the qubit is enabled and is responsive to the control signals.

The present invention will become readily apparent to those of ordinary skill in the art when descriptions of exemplary embodiments thereof are read with reference to the accompanying drawings.

### BRIEF DESCRIPTION OF THE DRAWINGS

FIG. 1 is a block diagram illustrating a Josephson-junction-based qubit, according to an exemplary embodiment of the present invention.

FIG. 2 is a block diagram illustrating a qubit circuit layout, according to an exemplary embodiment of the present invention.

FIG. 3 is a graph for illustrating example positions of a bias point of a qubit, according to an exemplary embodiment of the present invention.

FIG. 4 is a graph for illustrating example positions of a bias point of a qubit, according to an exemplary embodiment of the present invention.

FIG. 5 is a graph for illustrating example positions of a bias point of a qubit, according to an exemplary embodiment of the present invention.

FIG. 6 is a block diagram illustrating a system for quantum computing including a control system for controlling a plurality of qubits, according to an exemplary embodiment of the present invention.

FIG. 7 is a block diagram illustrating a select/deselect signal source, according to an exemplary embodiment of the present invention.

FIG. 8 is a flowchart illustrating a method of controlling a quantum system comprising a plurality of qubits, according to an exemplary embodiment of the present invention.

### DESCRIPTION OF EXEMPLARY EMBODIMENTS

Hereinafter, exemplary embodiments of the present invention will be described with reference to the accompanying drawings. As used herein, the term “room temperature” refers to ambient or atmospheric temperature. In general, room temperature may be taken to be about 20° C. to about 25° C.

It is to be understood that exemplary embodiments of the present invention described herein may be implemented in various forms of hardware, software, firmware, special purpose processors, or a combination thereof. An exemplary embodiment of the present invention may take the form of an entirely hardware embodiment, an entirely software embodiment or an embodiment is containing both hardware and software elements. An exemplary embodiment may be implemented in software as an application program tangibly embodied on one or more program storage devices, such as for example, computer hard disk drives, CD-ROM (compact disk-read only memory) drives and removable media such as CDs, DVDs (digital versatile discs or digital video discs), Universal Serial Bus (USB) drives, floppy disks, diskettes and tapes, readable by a machine capable of executing the program of instructions, such as a computer. The application program may be uploaded to, and executed by, an instruction execution system, apparatus or device comprising any suitable architecture. It is to be further understood that since exemplary embodiments of the present invention depicted in the accompanying drawing figures may be implemented in software, the actual connections between the system components (or the flow of the process steps) may differ depending upon the manner in which the application is programmed.

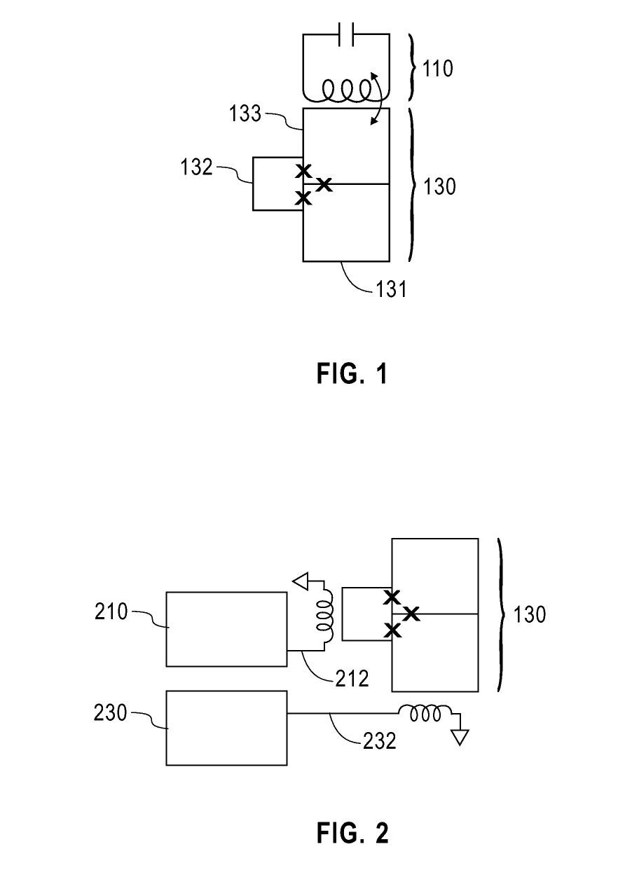

FIG. 1 is a block diagram illustrating a Josephson-junction-based qubit, according to an exemplary embodiment of the present invention. Referring to FIG. 1, the Josephson-junction-based qubit 130 consists of three thin wire loops 131, 132, 133 connected as shown and three Josephson junctions, indicated by the X's, with two in each loop. A Josephson-junction-based qubit 130 may be, for example, about 400 μm by about 800 μm in size. The qubit 130 may operate at about 20 mK.

In the Josephson-junction-based qubit 130 shown in FIG. 1, the upper large loop 133 of the qubit 130 is coupled to an LC oscillator circuit 110, which allows the quantum information in the qubit 130 to be transferred reversibly between the three loops 131, 132, 133 and the LC circuit 110. The LC circuit 110 may be implemented using a superconducting transmission line, for example.

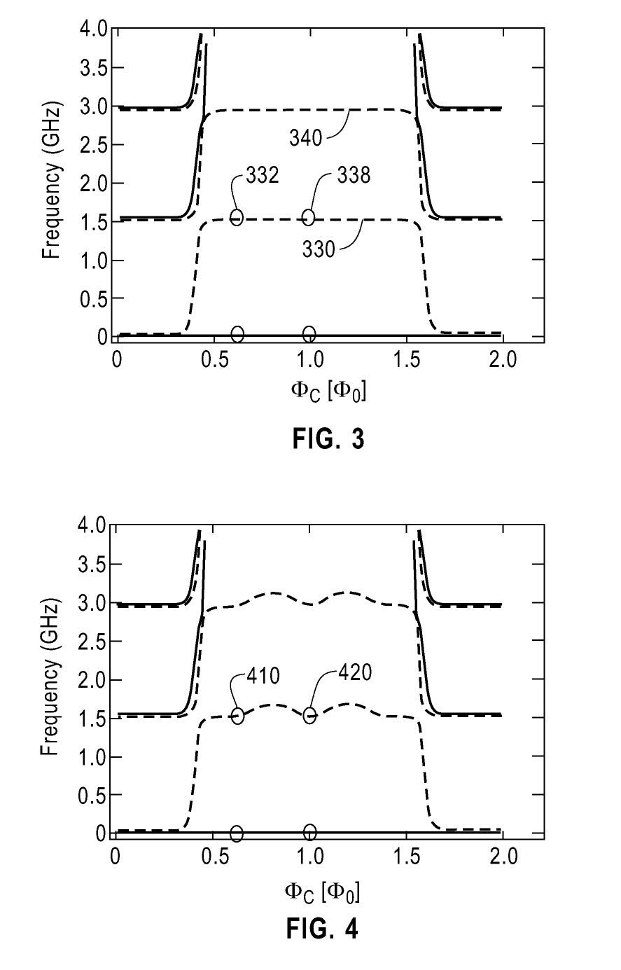

When the quantum information is located in the LC circuit 110, according to an exemplary embodiment of the present invention the operating frequency system is independent of the control parameters. This will be discussed later in this disclosure with reference to FIGS. 3-5. Two control lines may be employed to operate the Josephson-junction-based qubit 130 shown in FIG. 1. For example, a cflux line 212 and a flux line 232, as shown of FIG. 2, can be used to operate a Josephson-junction-based qubit 130.

FIG. 2 is a block diagram illustrating a qubit circuit layout, according to an exemplary embodiment of the present invention. Referring to FIG. 2, the control signals in the cflux line 212 and the flux line 232 are inductively coupled to the qubit 130. Depending on the nature of the desired quantum operation, the control signals may consist of DC, short duration pulses or pulsed microwaves, for example. The flux control signal source 230 and cflux control signal source 210 may be at room temperature.

In an exemplary embodiment of the present invention, a system for quantum computing includes a plurality of qubits and a control system for controlling the qubits. Signals from two types of signal sources may be combined to operate a qubit. A qubit may comprise, for example, quantum dots, electron and nuclear spins, or Josephson junctions. The qubits may be superconducting qubits.

The first type of signal source may be, for example, a signal source operating in a room-temperature environment (also referred to herein as a “room-temperature signal source”). Examples of a room-temperature signal source include a precision current source, a precision current source that provides continuously variable current, current or voltage pulse sources, a frequency adjustable microwave current or voltage source, e.g., with the ability to shape the pulse in frequency and amplitude, and any adjustable current source that is capable of supplying about 1 μA (micro Ampere) to about 1000 μA operating in a room-temperature environment. In an exemplary embodiment of the present invention, the first type of signal source is a precision current source that provides continuously variable current that may vary from about 1 nA (nano Ampere) to about 10 mA (milli Ampere).

The second type of signal source may be, for example, a cryogenic current source, such as a low-power cryogenic current source. Various different low-power cryogenic current sources that provide stable, reliable, low-power current may be suitable for implementing the second type of signal source. The second type of signal source may have limited variably. In an exemplary embodiment of the present invention, the second type of signal source is a low-power cryogenic current source using SFQ (Single Flux Quantum) circuits capable of providing precise current pulses that vary from about 1 μA to about 1 mA.

FIG. 3 is a graph for illustrating example positions of a bias point of a qubit, according to an exemplary embodiment of the present invention. FIG. 3 shows the measured frequency (GHz) versus control flux, which is denoted by Φ_{c}[Φ₀]. Referring to FIG. 3, two examples of a qubit operating characteristic curve 330 and 340 are shown. In a quantum system, information processing may require that each qubit is biased at a “bias position” 332, as depicted in FIG. 3. If a cflux 20 control line pulse is applied to a qubit array, according to an exemplary embodiment of the present invention, any qubit biased at the bias position 332 will execute a gate, depending on the magnitude and duration of the cflux control line pulse and the value of the applied flux to the qubit. The timing and precision of the cflux control pulse, for example, may be controlled using a room-temperature source of the control line cflux pulse.

In an exemplary embodiment of the present invention, a select/deselect signal source provides a select/deselect signal to move a qubit bias point from the bias position 332 to a “deselect position” 338, as shown in FIG. 3. When a qubit is biased at the deselect position 338, the application of the cflux control line pulse to move the bias point to the bias position 332 will not change the state of the qubit. That is, over the range in cflux from the deselect position 338 to the bias position 332 the qubit eigenfrequency, i.e., the operating frequency, is unchanged.

To minimize the room-temperature-to-30-mK connections, one cflux control line may be connected to many qubits. However, in operation of “logical qubits”, during any one cflux pulse, only a fraction of the qubits may be required to operate. A “logical qubit” may be composed of a main qubit and a plurality of error-correction qubits. Qubits not required for a computation may be biased at the “deselected position”, and qubits that are required to operate may be biased at the “bias position”.

The bias point may be set using a plurality of select/deselect signal sources each coupled to a corresponding one of the qubits. In an exemplary embodiment of the present invention, each select/deselect signal source independently operates to set a bias point of the corresponding qubit between a first position, in which the qubit is disabled and not responsive to the control signals, and a second position, in which the qubit is enabled and is responsive to the control signals.

The magnitude and duration of the cflux control pulses may be continuously variable. In an exemplary embodiment of the present invention, the rise and fall times of the cflux control pulses are controlled and have values on the order of 1 ns (nanosecond).

The requirements for the select/deselect signal source may differ from those for cflux control pulses. The rise and fall times of a select/deselect current pulse may be relatively long and the magnitude and duration of the select/deselect pulses may be quantized. However, the magnitude and duration of the select/deselect pulses do not need to be continuously variable.

The select/deselect signal source may be realized by an SFQ (Single Flux Quantum) based current source. For example, the SFQ-based current source may provide a quantized current with a rise time of 10 ns by applying 100 flux quanta into a loop in 10 ns. Where the inductance value is 1 nH, for example, the SFQ current source may provide a select/deselect current of 200 μA. The SFQ-based source may be constructed on a chip or chips other than the qubit chip, whereby the heat generated by the SQF pulses would not warm the qubit chip. The connection between the SFQ-based source and the qubit chip may be filtered, which may help to reduce the interference between the qubit and the SFQ circuits. A filter may comprise one or more signal filters to attenuate and filter noise.

In an exemplary embodiment of the present invention, a system for quantum computing includes a plurality of qubits and a control system for controlling the qubits. For example, the qubits may comprise quantum dots, electron and nuclear spins, or Josephson junctions. The qubits may be superconducting qubits. The control system, according to an exemplary embodiment of the present invention, generates control signals to control operation of the qubits and sets a bias point of each qubit between a first position, in which the qubit is disabled and not responsive to the control signals, and a second position, in which the qubit is enabled and responsive to the control signals. A control signal may be an electrical current, a voltage, or any other signal.

In an exemplary embodiment of the present invention, a control system for controlling a plurality of qubits includes a control signal source, commonly coupled to each qubit, and a plurality of select/deselect signal sources each coupled to a corresponding one of the qubits. The control signal source commonly coupled to each qubit generates control signals to control operation of the qubits. Each select/deselect signal source independently operates to set a bias point of the corresponding qubit between a first position, in which the qubit is disabled and not responsive to the control signals, and a second position, in which the qubit is enabled and is responsive to the control signals.

FIG. 4 is a graph for illustrating example positions of a bias point of a qubit, according to an exemplary embodiment of the present invention. FIG. 4 shows the measured frequency (GHz) versus control flux, which is denoted by Φ_{c}[Φ₀]. FIG. 4 illustrates the case where the operating frequency of a qubit is not independent of bias over a large range, but because of the physical makeup of the qubit, satisfies the weaker condition that the frequency is only identical at two points.

In the simpler case of FIG. 3, any qubit that makes the transit from the deselect point to the bias point is unaffected since the operating frequency is substantially the same before, during, and after the transit. For the example qubit depicted in FIG. 4, the operating frequency before and after the transit from the deselect point 420 to the bias point 410 will be substantially the same, but during the transit there will be some change in the state of the qubit since the frequency changes for the depicted qubit. The process of operating multiple qubits that have operating characteristics shown in FIG. 4 may require that a record be kept of the number of transits for each qubit and/or may require corrections to be applied. However, the additional complexity required on the system level may be minimal compared to the flexibility achieved in being able to select and deselect qubits for operation that have operating characteristics shown in FIG. 4.

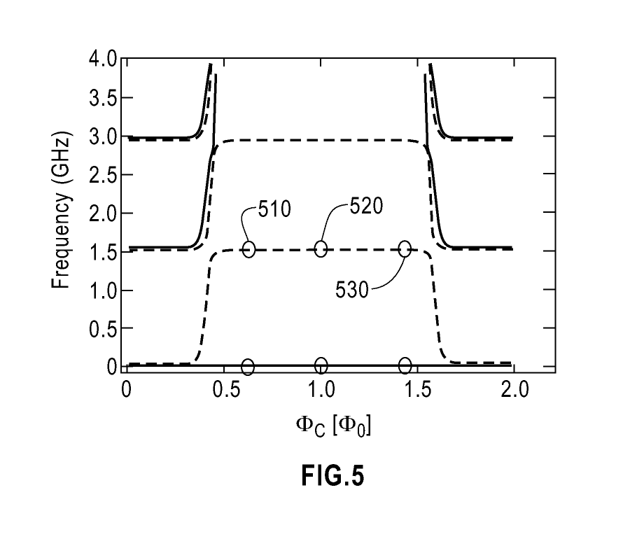

FIG. 5 is a graph for illustrating example positions of a bias point of a qubit, according to an exemplary embodiment of the present invention. FIG. 5 shows the measured frequency (GHz) versus control flux, which is denoted by Φ_{c}[Φ₀]. FIG. 5 demonstrates that if a qubit has an operating frequency that is independent of the control parameter (the x-axis variable) over a large range, then multiple deselected positions may be used. For example, the qubit may be biased at the “unenabled position” or at the “second possible unenabled position” without changing the time evolution of the qubit information.

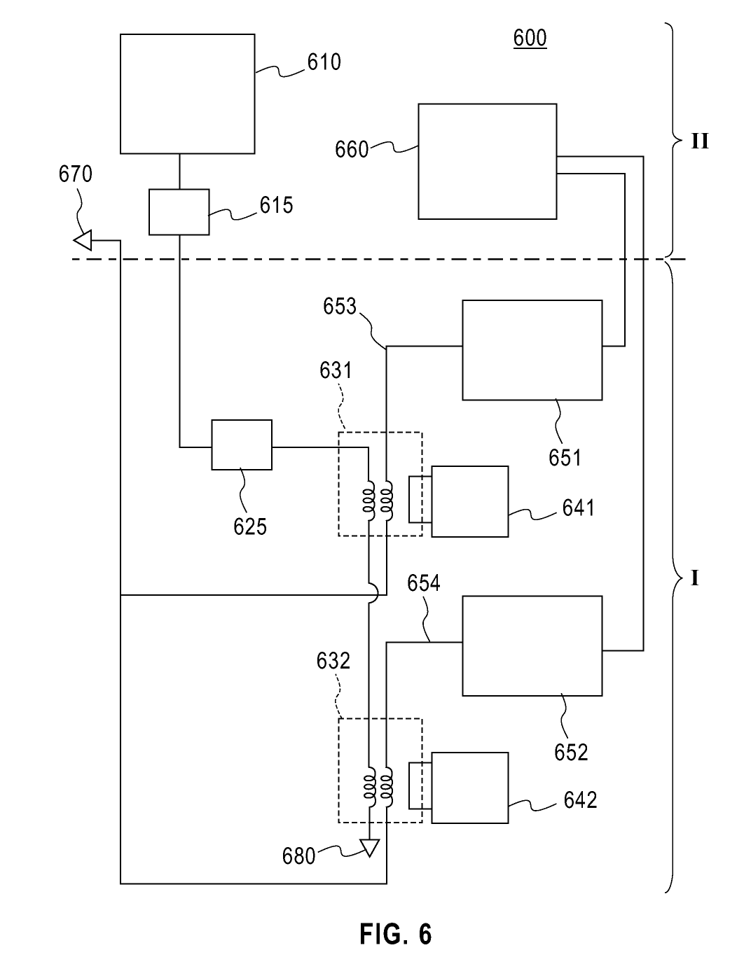

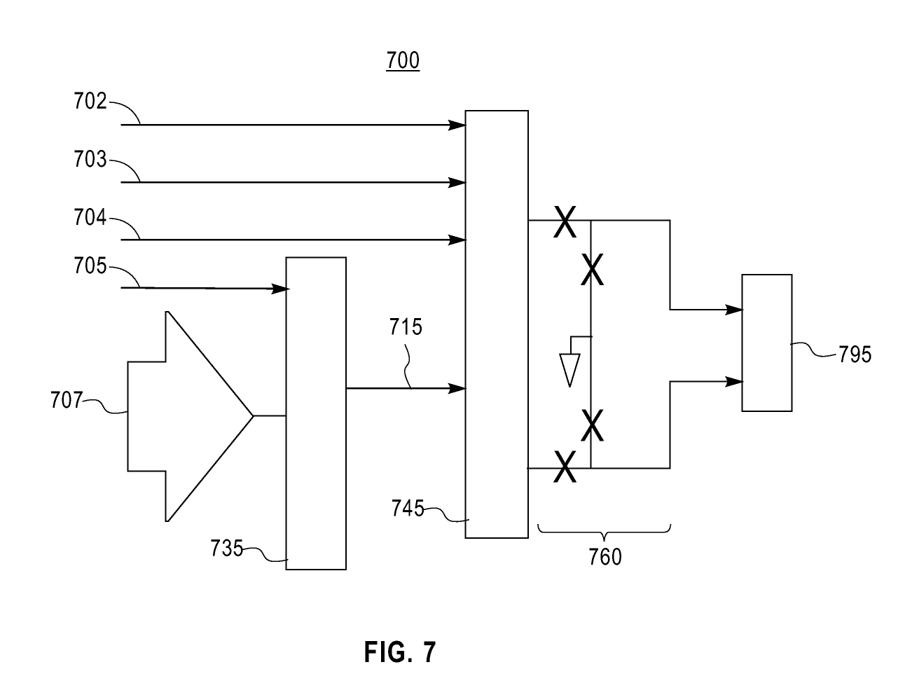

In an exemplary embodiment of the present invention described in connection with FIGS. 6 and 7, select/deselect circuitry can be used to move the operating point of the qubit, for example, from the bias position 332 to a deselect position 338 as depicted on the FIG. 3. This flexibility in operation can make the overall layout of the control system simpler. In an exemplary embodiment of the present invention, any qubit that should have a gate applied would be required to satisfy two independent addressing conditions.

FIG. 6 is a block diagram illustrating a system for quantum computing including a control system for controlling a plurality of qubits, according to an exemplary embodiment of the present invention. Referring to FIG. 6, the system 600 includes a first qubit 641, a second qubit 642, a first select/deselect signal source 651, a second select/deselect signal source 652, a control signal source 610, and address and signal lines 660. Although two qubits and two corresponding select/deselect signal sources are shown in FIG. 6, it is to be understood that any number of qubits and select/deselect signal sources may be employed. A first filter 615 and a second filter 625 may be provided, for example. The filter and second filters 615 and 625 may comprise one or more signal filters to attenuate and filter noise.

The first and second qubits 641 and 642 may operate in a first environment I having a first temperature range. The first and second select/deselect signal sources 651 and 652 may also operate in the first environment I having the first temperature range. The first temperature range may be, for example, about 5 mK to about 30 mK. The control signal source 610 may operate in a second environment II having a second temperature range. For example, the second temperature range may about 20° C. to about 25° C.

The control signal source 610, which is electrically coupled to the first and second qubits 641 and 642, generates control signals to control operation of the first and second qubits 641 and 642. A control signal may be an electrical current, a voltage, or any other signal. In an exemplary embodiment of the present invention, the control signals are applied using a superconducting SFQ circuit.

The bias points of the first and second qubits 641 and 642 may be set using the first and second select/deselect signal sources 651 and 652, respectively. The first select/deselect signal source 651 and/or second select/deselect signal sources 652 may be a superconducting SFQ circuit.

In the case when qubits are configured with a single input terminal, as in the example shown in FIG. 6, signal adders may be employed. For example, the signal adders may be superconducting current adders. As shown in FIG. 6, the system 600 includes a first current adder 631, which is coupled to the first select/deselect signal source 651 via line 653, and a second current adder 632, which is coupled to second select/deselect signal source 652 via line 654. Although not shown as such in FIG. 6, it will be appreciated that qubits can have a plurality of input terminals and signal adders may not be needed.

The first current adder 631, for example, is coupled to an input terminal of the first qubit 641, wherein the first current adder 631 includes a first input terminal commonly coupled to the control signal source 610 and a second input terminal coupled to the first select/deselect signal source 651 via line 653. The first current adder 631 operates to add current flowing into the first current adder 631 through the first and second input terminals and applies a current to the input terminal of the first qubit 641.

FIG. 7 is a block diagram illustrating a select/deselect signal source, according to an exemplary embodiment of the present invention. Referring to FIG. 7, the select/deselect circuit 700 is implemented using superconducting SFQ logic. It is to be understood that the select/deselect signal source may be embodied in many different forms or configurations.

In an exemplary embodiment of the present invention, the SFQ-based select/deselect circuit 700 functions as a current source to precisely move the operating point of the qubit, for example, from a deselect position 338 to the bias position 332, as shown in FIG. 3. The select/deselect circuit 700 may be employed to move the operating point of the qubit between an “unenabled position” 520 and a “bias position” 510 and/or to other possible operating point(s) of the qubit, such as a second deselected position 530, as shown in FIG. 5.

In an exemplary embodiment of the present invention, the SFQ-based select/deselect circuit 700 switches about ˜0.5 mA in about 12 ns. Select/deselect circuit 700 is designed to quickly accept addresses and latch the enable line. In this way, for example, a large number of select/deselect circuits can be enabled in a short period of time. At that point, a (global) signal on the count up line 703 or count down line 702 will move all the selected qubits between the two operating points. A global reset line 704 can be employed to reset all the circuits to the unenabled state.

In an exemplary embodiment of the present invention, operation of the select/deselect circuit 700 is initiated when then the (global) data valid line 705 is true and the unique address for a particular qubit is present on the, for example, 14 address lines 707. When the hard-wired SFQ address multiplexer 735 asserts the latching enable line 715 true, this enables the clockable SFQ pulse injector 745 to count up or down depending on the (global) signals on the count up clock or count down clock lines.

The pulse injector 745 injects pulses into the Josephson junction circuit 760, which effectively sums the pulses and applies them to the qubit 795 via, for example via a current adder. When selected, via the latching enable line 715 being true, the pulse injector 745 will move the bias position of the attached qubit 795 from the bias and deselected as the count up and down clock lines 703 and 702 are clocked. At the end of the operation, the assertion of the global reset line 704 true resets all the pulse injectors 745 to the disabled mode.

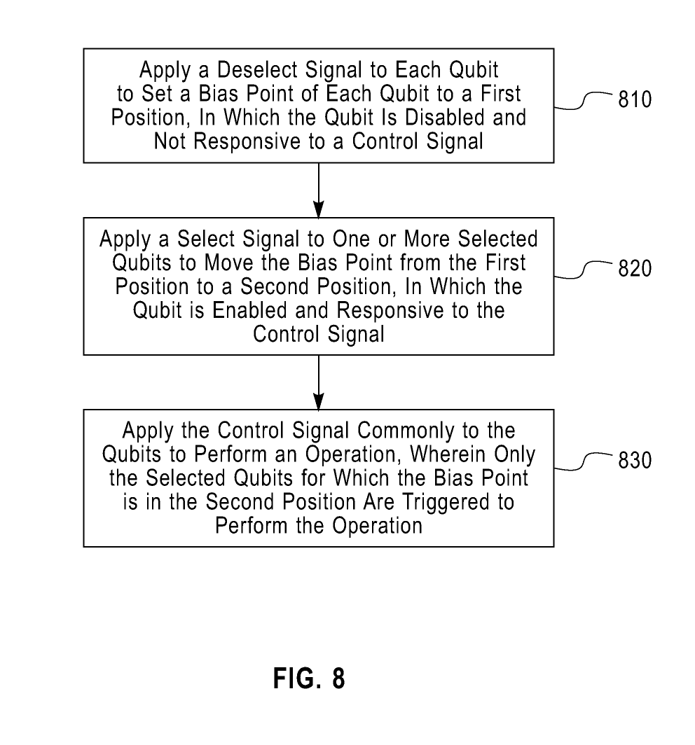

FIG. 8 is a flowchart illustrating a method of controlling a quantum system comprising a plurality of qubits, according to an exemplary embodiment of the present invention. For example, the qubits may comprise quantum dots, electron and nuclear spins, or Josephson junctions. The qubits may be a superconducting qubits.

Referring to FIG. 8, in step 810, apply a deselect signal to each qubit to set a bias point of each qubit to a first position, in which the qubit is disabled and not responsive to a control signal. The deselect signal may be an electrical current, a voltage, or any other signal. In an exemplary embodiment of the present invention, the bias point is a current bias point and the deselect signal is an electrical current. Setting the bias point of each qubit to the first position may include using a plurality of select/deselect signal sources each coupled to a corresponding one of the qubits. Each select/deselect signal source may be, for example, a superconducting SFQ circuit.

In step 820, apply a select signal to one or more selected qubits to move the bias point from the first position to a second position, in which the qubit is enabled and responsive to the control signal. The select signal may be an electrical current, a voltage, or any other signal.

In step 830, apply the control signal commonly to the qubits to perform an operation, wherein only the selected qubits for which the bias point is in the second position are triggered to perform the operation. The control signal may be an electrical current, a voltage, or any other signal. The control signal may be applied using a superconducting SFQ circuit.

In an exemplary embodiment of the present invention, the qubits operate in a first environment having a first temperature range, and the control signal is applied using a control signal source that operates in a second environment having a second temperature range. The first temperature range may be, for example, about 5 mK to about 30 mK. The second temperature range may be about 20° C. to about 25° C.

In an exemplary embodiment of the present invention, the qubits and the select/deselect signal sources operate in a first environment having a first temperature range, and the wherein the control signal is applied using a control signal source that operates in a second environment having a second temperature range. For example, the first temperature range may be about 5 mK to about 30 mK. The second temperature range may be about 20° C. to about 25° C.

In an exemplary embodiment of the present invention, a method of controlling a plurality of qubits includes providing a plurality of qubits, wherein each of the qubits has at least two bias points on an operating characteristic of the qubit for which the lowest eigen-frequency is substantially the same, and generating signals for moving the bias point of selected qubits between the at least two bias points. The qubits may comprise quantum dots, electron and nuclear spins, or Josephson junctions, for example. The qubits may be a superconducting qubits. The signals for moving the bias point of selected qubits may be generated using a plurality of select/deselect signal sources, which may be superconducting SFQ (Single Flux Quantum) circuits.

Although exemplary embodiments of the present invention have been described in detail with reference to the accompanying drawings for the purpose of illustration and description, it is to be understood that the inventive processes and apparatus are not to be construed as limited thereby. It will be apparent to those of ordinary skill in the art that various modifications to the foregoing exemplary embodiments may be made without departing from the scope of the invention as defined by the appended claims, with equivalents of the claims to be included therein.

What is claimed is:

1 A system for quantum computing, comprising:
a plurality of qubits; and
a control system that generates control signals to control operation of the qubits and sets a bias point of each qubit between a first position, in which the qubit is disabled and not responsive to the control signals, and a second position, in which the qubit is enabled and responsive to the control signals.

2. The system of claim 1, wherein the qubits comprise Josephson junctions.

3. The system of claim 1, wherein the qubits comprise electron and nuclear spins.

4. The system of claim 1, wherein the qubits comprise quantum dots.

5. The system of claim 1, wherein the control signal is applied using a superconducting SFQ (Single Flux Quantum) circuit.

6. The system of claim 1, wherein the bias point is set using a plurality of select/deselect signal sources each coupled to a corresponding one of the qubits.

7. The system of claim 6, wherein each select/deselect signal source is a superconducting SFQ (Single Flux Quantum) circuit.

8. A program storage device readable by machine, tangibly embodying a program of instructions executable by the machine to perform method steps for controlling a quantum system comprising a plurality of qubits, the method steps comprising:
applying a deselect signal to each qubit to set a bias point of each qubit to a first position, in which the qubit is disabled and not responsive to a control signal;
applying a select signal to one or more selected qubits to move the bias point from the first position to a second position, in which the qubit is enabled and responsive to the control signal; and
applying the control signal commonly to the qubits to perform an operation, wherein only the selected qubits for which the bias point is in the second position are triggered to perform the operation.

9. The program storage device of claim 8, wherein the qubits comprise Josephson junctions.

10. The program storage device of claim 8, wherein the qubits comprise electron and nuclear spins.

11. The program storage device of claim 8, wherein the qubits comprise quantum dots.

12. A method of controlling a plurality of qubits, comprising:
providing a plurality of qubits, wherein each of the qubits has at least two bias points on an operating characteristic of the qubit for which the lowest eigen-frequency is substantially the same; and
generating signals for moving the bias point of selected qubits between the at least two bias points.

13. A control system for controlling a plurality of qubits, the control system comprising:
a control signal source commonly coupled to each qubit, which generates control signals to control operation of the qubits; and
a plurality of select/deselect signal sources each coupled to a corresponding one of the qubits, wherein each select/deselect signal source independently operates to set a bias point of the corresponding qubit between a first position, in which the qubit is disabled and not responsive to the control signals, and a second position, in which the qubit is enabled and is responsive to the control signals.

14. The control system of claim 13, further comprising a plurality of current adders, each current adder coupled to an input terminal of a corresponding qubit, wherein each current adder comprises a first input terminal commonly coupled to the control signal source and a second input terminal coupled to a select/deselect signal source for the corresponding qubit, wherein the current adder operates to add current flowing into the current adder through the first and second input terminals and applies a current to the input terminal of a corresponding qubit.

15. The control system of claim 13, wherein the qubits comprise Josephson junctions.

16. The control system of claim 13, wherein the qubits comprise electron and nuclear spins.

17. The control system of claim 13, wherein the qubits comprise quantum dots.

18. The control system of claim 13, wherein the qubits and the select/deselect signal sources operate in a first environment having a first temperature range and the control signal source operates in a second environment having a second temperature range.

19. The control system of claim 18, wherein the first temperature range is about 5 mK to about 30 mK and the second temperature range is about 20° C. to about 25° C.

20. The control system of claim 18, wherein the first temperature range is substantially equal to the second temperature range.
